(19) United States
(12) Patent Application Publication
(10) Pub. No.: US 2004/0061122 A1
(43) Pub. Date: Apr. 1, 2004

(54) Light emitting device with low back facet reflections

(76) Inventor: Gerard Alphonse, Princeton, NJ (US)

Correspondence Address: INTELLECTUAL PROPERTY DOCKET ADMINISTRATOR, GIBBONS, DEL DEO, DOLAN, GRIFFINGER & VECCHIONE, 1 RIVERFRONT PLAZA, NEWARK, NJ, 07102, US

(21) Appl. No.: 10/461,023

(22) Filed: Jun. 13, 2003

Related U.S. Application Data
(60) Provisional application No. 60/414,277, filed on Sep. 27, 2002.

(51) Int. Cl. H01L 33/00

(52) U.S. Cl. 257/94; 257/95

(57) ABSTRACT

Back facet reflections are substantially minimized in a tilted, ridge wave-guide SLD. One end of the wave-guide terminates at the front facet and the other end terminates proximate, but not necessarily at, the back facet. The back facet termination includes a radiating structure causing light to dissipate prior to striking the rear facet.

### CROSS-REFERENCE TO RELATED APPLICATIONS

This application claims priority to U.S. Provisional Application No. 60/414,277, filed on Sep. 27, 2002, entitled “Narrow Spectral Width Superluminescent Diodes Using Integrated Absorber,” and is related to U.S. application No. (SAR 14808) filed on ______, entitled “Narrow Spectral Width Light Emitting Devices.”

### FIELD OF THE INVENTION

The invention relates generally to light emitting devices, and more particularly to diode devices having spontaneous emissions without lasing.

### BACKGROUND

Superluminescent diodes (SLDs) are optical devices that provide amplified spontaneous emission outputs confined to one spatial mode. The spatial distribution of the output light is similar to a laser while the spectral distribution is similar to an LED. SLDs are often specified for applications requiring high beam quality, but where the narrow linewidth of the laser is undesirable or detrimental. An SLD typically has a structure similar to that of a laser, with lasing being prevented by antireflection coatings formed on the end faces. One such device is described in U.S. Pat. No. 4,821,277, which is incorporated herein by reference and which is characterized by a tilted waveguide structure. The axis of symmetry of the waveguide is formed at an angle relative to the direction perpendicular to at least one of the end faces and the tangent of the angle is greater than or equal to the width of the effective optical beam path divided by the length of the body between the end faces.

The SLD optical spectrum is just one measure of its performance. Another measure is its coherence spectrum, which consists of a narrow main peak and several other peaks of smaller amplitude. The smaller amplitude peaks are caused by reflections from the back facet and from imperfections in the waveguide. The largest peak besides the main peak is called the second coherence peak. Ideally, all peaks should be negligible in comparison to the main peak. But for certain applications, such as fiber optic gyroscopes and optical coherence tomography, the second coherence peak should be on the order of 30 dB below the main peak.

### SUMMARY

A light emitting device according to the principles of the invention substantially minimizes unwanted facet reflections. Light is dissipated or radiated away before the unwanted reflections occur. In one embodiment, back facet (also referred to as rear facet) reflections are substantially minimized in a tilted, ridge waveguide SLD, where the front facet is defined as the facet where the device emits light. One end of the waveguide terminates at the front facet, and the other end terminates proximate, but not necessarily at, the back facet. The back facet termination includes radiating structure, such as a curvature of a given radius or radii. This curvature causes light to dissipate prior to striking the rear facet. Further, the waveguide can include a pointed tip at the end proximate the rear facet and can terminate in an unpumped region of the device.

A method according to the principles of the invention includes the step of dissipating light prior to an unwanted reflection, and can include providing structure for uncoupling the device waveguide from unwanted reflections. The dissipating step can include terminating the waveguide a distance from the back facet and can include terminating the device in an unpumped region of the device. In one embodiment, the device is operated in a single mode.

### BRIEF DESCRIPTION OF THE DRAWINGS

In the Figures:

FIGS. 1A and 1B show a cross-sectional view and a top view respectively of a device according to the principles of the invention; and

FIG. 1C shows a detailed view of a portion of the device of FIG. 1.

### DETAILED DESCRIPTION

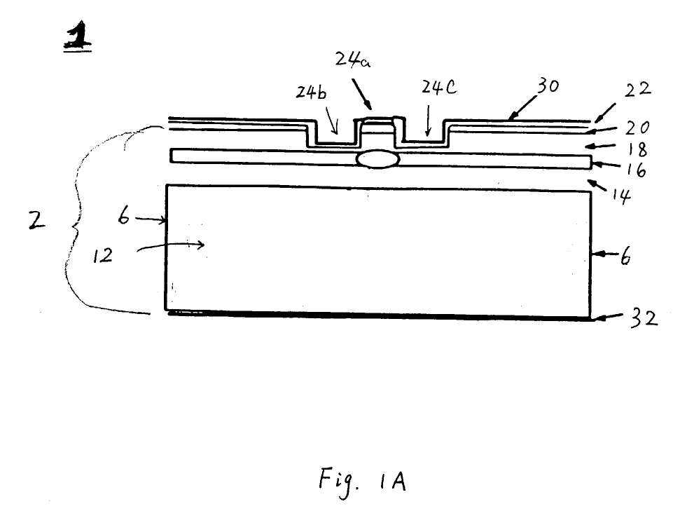

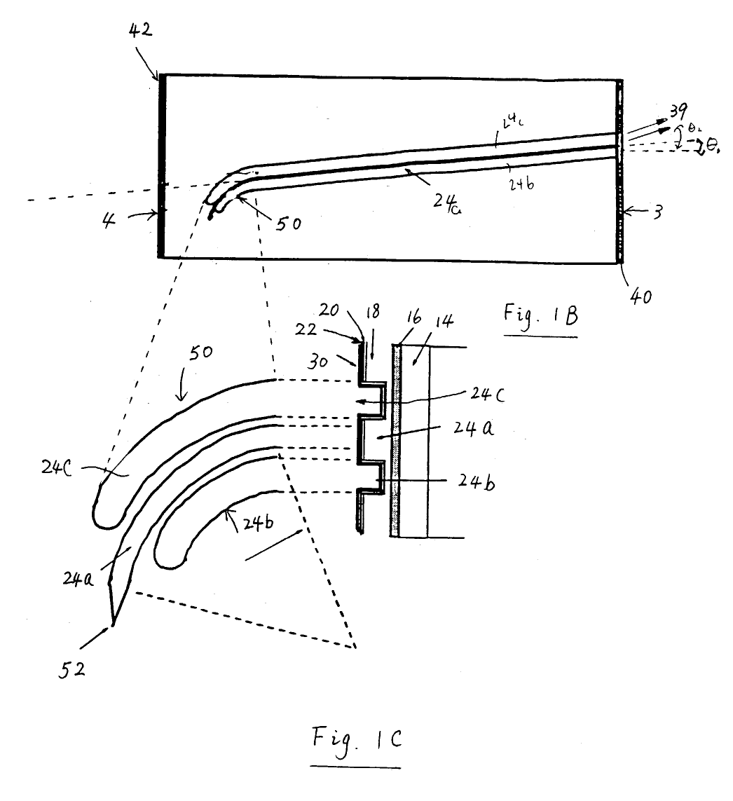

FIG. 1A shows a cross-sectional view of a light emitting device 1 according to the principles of the invention. In this example, the device 1 is a ridge waveguide SLD. The device 1 comprises a body 2 having opposed faces (not shown) and opposed sidewalls 6. The body 2 includes a substrate 12 having a first cladding layer 14 thereon, an undoped active layer overlying the first cladding layer 14, a second cladding layer 18 overlying the active layer 16, and a capping layer 20 overlying the second cladding layer 18. A dielectric layer 22 overlies the capping layer 20, except in the area of the waveguide 24a. An electrical contact 32 overlies the substrate and another electrical contact 30 overlies the dielectric layer 22, except in the area of the waveguide 24a which waveguide does not comprise a dielectric layer. Channels 24b, 24c are adjacent to the waveguide 24a.

In one embodiment, the undoped active layer 16 overlies a cladding layer 14 of one conductivity type, such as n-type, and has a cladding layer 18 of the opposite conductivity type, such as p-type, overlying it 16. These layers are deposited on the substrate 12, which is of the first conductivity type. For example, the substrate 12 can be n doped semiconductor material. In the exemplary configuration, the electrical contact 32 overlying the dielectric 22 is heavily doped p-type material and the other contact 30 is n-type. The channel regions 24b, 24c are formed by etching. Various materials can be used to make a light emitting device according to the principles of the invention. For example, the substrate can be GaAs and the active region can be materials such as GaAs, AlGaAs, or InGaAs. The cladding layers can be doped AsGaAs. In another example, the substrate can be doped InP and the active and clad layers can be InGaAsP of appropriate composition. Of course other materials can be used, such as other Group III-V compounds.

In a ridge waveguide configuration as described above, the effective refractive index in the channel regions is lower than that in the ridge by an amount which depends on the residual thickness of the p-clad material under the channels. Light is guided in the active layer under the ridge by virtue of the index difference between the ridge 24a and the channels 24b, 24c. Upon application of a voltage across the metal contacts 30, 32, current flows only through the region with the dielectric opening. At low current, the active layer 16 is absorbing, and the emitted light consists of spontaneous emission. Beyond a certain current, the spontaneous emission is amplified spontaneous emission. The light is guided along the ridge 24a and emitted at relatively high power. At these current values, the region with the current flow is called the pumped region. Current does not flow in the region of the semiconductor structure under the dielectric, and this region is the unpumped region. The unpumped region is absorbing.

For single mode operation, the lateral index step is given by

$$Δ n = {n}_{1} - {n}_{2} \leq \frac{{( \frac{λ}{W} )}^{2}}{4 ( {n}_{1} + {n}_{2} )} \qquad ( 1 )$$

where λ is the wavelength of the light, as shown in H. Kogelnik, Integrated Optics, 2d ed., Chap. 2, Springer-Verlak, New York. In this equation, W is the ridge width and the effective refractive indices under the channels are n1 and n2, respectively. λ is the wavelength of the light.

FIG. 1B shows a top view of the light emitting device 1. In this view, opposed facets 3, 4 are each coated with anti-reflecting coating 40 and 42 , respectively. The ridge waveguide 24a emits light at its 24a front facet 3 termination. The waveguide 24a forms an angle θ relative to the direction perpendicular to the front facet 3. The angle θ₂ of the output light 39 is larger than the angle of the waveguide, by virtue of Snell's law. The tilt angle, θ₁, can be any value below the critical angle at the front facet 3, at which point the output angle is 90°, and light cannot be coupled out of the device 1. In one embodiment, the tilt angle is 5° to 70°, which provides ease of coupling.

The curved section 50 proximate the rear or back facet 4 is a light dissipating structure. The curvature causes light to dissipate or radiate from the waveguide 24a before it can reflect back into the waveguide 24a from another facet, such-as the back facet 4. In this configuration, little or no light radiated from the waveguide 24a can reach the straight (amplification) section of the waveguide 24a.

A detailed view of the rear section of the waveguide 24a is shown in FIG. 1C, where the detail is projected from the top view of FIG. 1B and onto a cross-section of the device 1. In this detail, it is shown that the curvature of the channels 24b, 24c follows the curvature of the waveguide 24a for less than the length of the waveguide 24a. That is, the waveguide ridge 24a extends past the channels 24b, 24c. A termination structure 52, in this example a pointed or angular shaped tip, proceeds further than the channels 24b,c. The tip 52 radiates all rearward propagating light into an unpumped region, where it is absorbed. In this arrangement, little or no reflects can couple back into the waveguide 24a.

The radiation from a bent waveguide (or fiber) is determined by the radius of curvture of the bend. Radiation is small if the bend radius is larger than some, critical value, Rc, and it is large if the radius is much smaller than Rc. The critical radius is given by

$${R}_{c} = \frac{3}{2 π \sqrt{2}} \frac{\sqrt{{n}_{1}}}{{( Δ n )}^{3 / 2}} λ , \qquad ( 2 )$$

where Δn is given by equation (1) above for a single-mode waveguide. See E. A. J. Marcatili, Bell System Tech Journal, p. 2103-2132, September 1969. Where a curved radiating structure is used, the radius of curvature should be chosen much less than Rc as limited by practical considerations. In one aspect, a first radius of curvature can be chosen closer to Rc, and, after some radiating effect, a second smaller radius of curvature can be chosen. Of course, the optimal radius or radii, can be found using trial and error or other techniques depending upon the precise light emitting device and application under consideration.

A light emitting devices according to the principles of the invention substantially improve spectral modulation to less than 2 percent, and can achieve attenuation of second coherence peaks on the order of 30 dB or greater. Such devices can be used in a variety of applications, including FOGs, and communication devices.

While the principles of the invention have been illustrated using a ridge waveguide SLD, it should be apparent that the invention is not limited to this application. Any radiating structure used to dissipate light prior to facet reflections can be used without departing from the principles of the invention. For example, merely terminating a waveguide in an unpumped region some distance from a back facet could achieve a decrease in back facet reflections. Similarly, the light dissipating structure should not be considered limited to curved structures. Other types of dissipating structures can be used without departing from the invention.

What is claimed is:

1. A light emitting device comprising:
a body having at least one facet and an active region;
a waveguide arranged to form an effective optical beam path at said active region, the waveguide having an end terminating at the at least one facet and another end including a light radiating structure arranged to dissipate light reflected from the at least one facet and propagating to another end prior to a reflection from at least another facet, the device outputting light at the end terminating at the at least one facet.

2. The light emitting device of claim 1 wherein the light radiating structure includes a termination portion wherein the optical beam path defines a nonlinear path.

3. The light emitting device of claim 2 wherein the light radiating structure defines an arc.

4. The light emitting device of claim 3 wherein the arc is prescribed by a plurality of radii.

5. The light emitting device of claim 1 wherein the light radiating structure includes a tip.

6. The light emitting device of claim 3 wherein the light radiating structure includes a tip.

7. The light emitting device of claim 1 wherein the body includes another facet substantially opposed to the at least one facet, wherein the another end terminates a distance from the another facet.

8. The light emitting device of claim 7, the body further including a pumped region and an unpumped region, wherein the another end terminates in the unpumped region.

9. The light emitting device of claim 8 wherein the waveguide comprises a ridge waveguide.

10. The light emitting device of claim 1 wherein the waveguide operates in a single transverse mode.

11. The light emitting device of claim 1 wherein the waveguide comprises a tilted waveguide.

12. The light emitting device of claim 1 wherein a spectral modulation of emitted light has a value of less than 2%.

13. The light emitting device of claim 1 wherein a spectrum of the emitted light has a second coherence peak at least 30 dB below a first coherence peak.

14. A method of operating a superluminescent diode having a waveguide and a plurality of facets, the method comprising the steps of:
outputting forward propagating light at a front facet; and
radiating rearward propagating light reflected from the front facet away from a rear facet in avoidance of reflection from the rear facet.

15. The method of claim 14 wherein the radiating step includes increasing an incidence angle at the rear facet for the rearward propagating light relative to an incidence angle at the front facet for the forward propagating light.

16. The method of claim 14 wherein the radiating step includes curving an end of the waveguide proximate the rear facet.

17. The method of claim 14 wherein the radiating step includes terminating an end of the waveguide proximate the rear facet a distance from the rear facet.

18. The method of claim 14 wherein the radiating step includes radiating the rearward propagating light in an unpumped region of the superluminescent diode.

19. A light emitting device comprising:
a body having a plurality of facets; and
a single-transverse-mode tilted waveguide having at least one termination at one of the facets and means for substantially reducing reflections from at least another of the facets.

20. The light emitting device of claim 19 wherein the means for substantially reducing reflections from at least another of the facets includes:
at least another termination a distance from at least another of the facets, the waveguide prescribing a substantially linear section, which includes the at least one termination, and a nonlinear section.

21. The light emitting device of claim 20 wherein the means for substantially reducing reflections from at least another of the facets includes a tip at the at least another termination.
